(19) United States
(12) Patent Application Publication
(10) Pub. No.: US 2026/0206290 A1
(43) Pub. Date: Jul. 16, 2026

(54) SEMICONDUCTOR STRUCTURE HAVING LOGIC VIAS AND MEMORY VIAS WITH DIFFERENT DEPTHS AND METHOD FOR MANUFACTURING THE SAME

(71) Applicant: TAIWAN SEMICONDUCTOR MANUFACTURING COMPANY, LTD., Hsinchu (TW)

(72) Inventors: Ming-Heng TSAI, Hsinchu (TW); Ta-Chun LIN, Hsinchu (TW); Jhon Jhy LIAW, Hsinchu (TW)

(73) Assignee: TAIWAN SEMICONDUCTOR MANUFACTURING COMPANY, LTD., Hsinchu (TW)

(21) Appl. No.: 19/020,243

(22) Filed: Jan. 14, 2025

(51) Int. Cl. H10D 84/01; H10D 84/85

(52) U.S. Cl. CPC H10D 84/0186; H10D 84/0167; H10D 84/017; H10D 84/851

(57) ABSTRACT

A method for manufacturing semiconductor structure includes: forming first devices and second devices on a substrate, each of the first devices and the second devices including a source/drain portion and channel features that are connected to the source/drain portion; forming first device vias, each of which penetrates through the substrate and is connected to the source/drain portion of a respective one of the first devices; and forming second device vias, each of which penetrates through the substrate and is connected to the source/drain portion of a respective one of the second devices, a depth of the first device vias being different from a depth of the second device vias.

### BACKGROUND

A semiconductor structure may simultaneously include both logic devices and memory devices. It is noted that each of the logic devices and the memory devices demonstrate desirable performances under different electrical parameters. Thus, novel structures and processes for manufacturing the same are proposed to boost performances of both the logic devices and the memory devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 31 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±30%, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Source/drain portion(s) may refer to a source or a drain, individually or collectively dependent upon the context.

The present disclosure is directed to a semiconductor structure having logic vias and memory vias with different depths, and method for manufacturing the same. The logic vias and the memory vias serve as back side vias that penetrate through a substrate, and that are connected to source/drain portions of logic devices and memory devices, respectively. The logic vias may be formed with a relatively greater depth, so that the logic devices achieve a relatively smaller contact resistance level. The memory vias may be formed with a relatively smaller depth, so that the memory devices achieve a relatively less current leakage. As such, performance of both the logic devices and the memory devices can be significantly enhanced. In addition, the back side vias for p-type devices may be formed with a depth smaller than that of the back side vias for n-type devices, so that a larger volume of the source/drain portions of the p-type devices may be retained to induce sufficient amount of stress in channel features of the p-type devices, thereby further improving performance of the p-type devices.

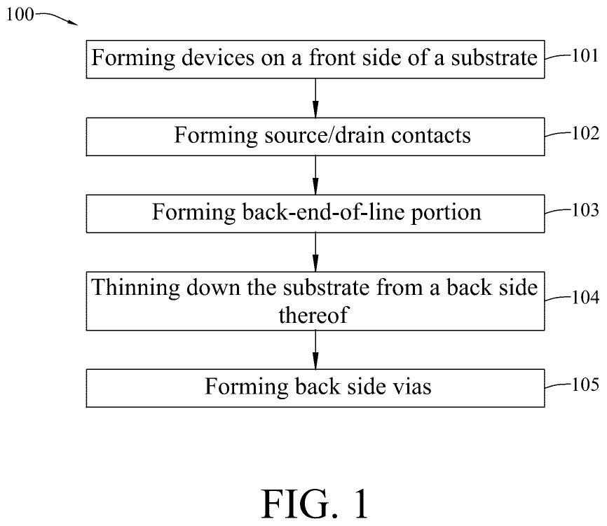

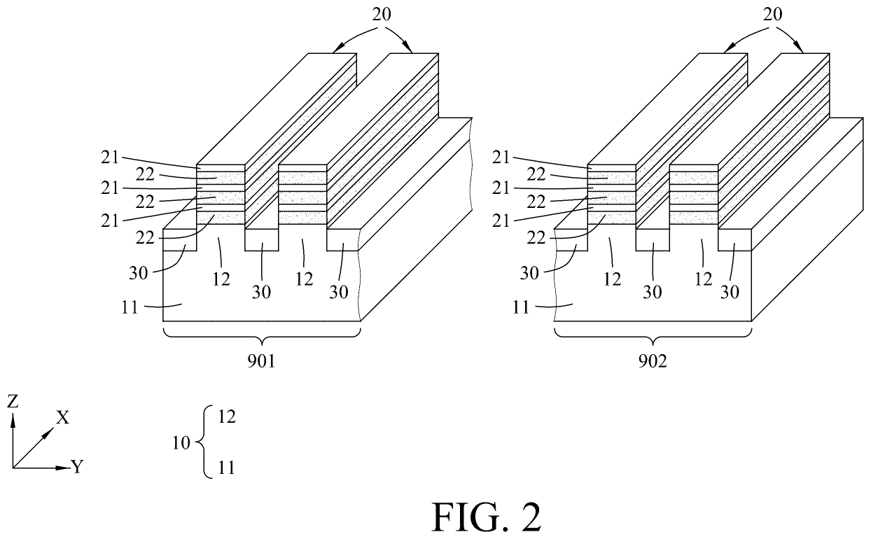

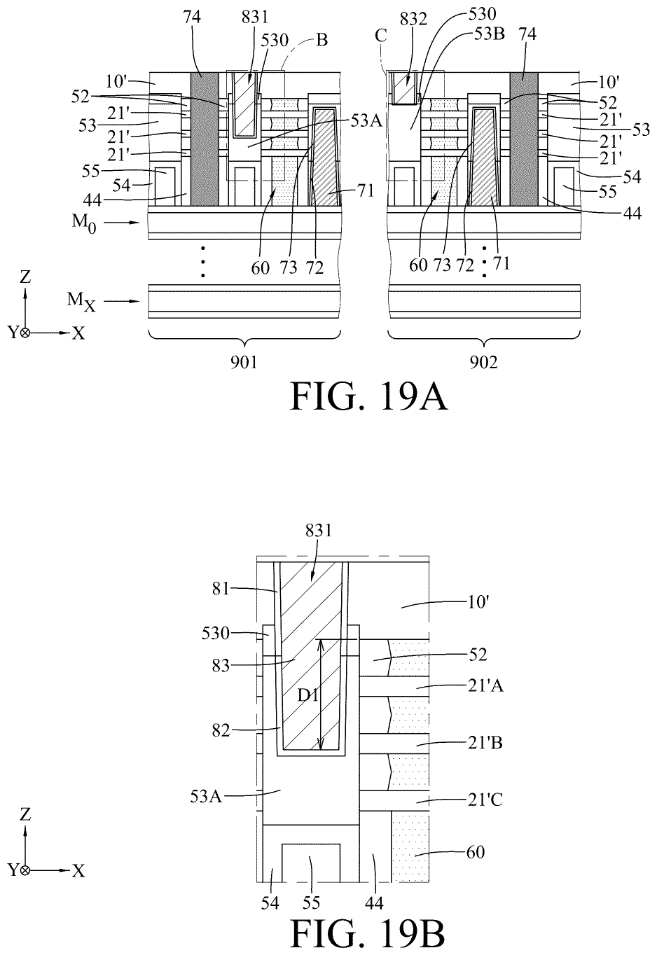

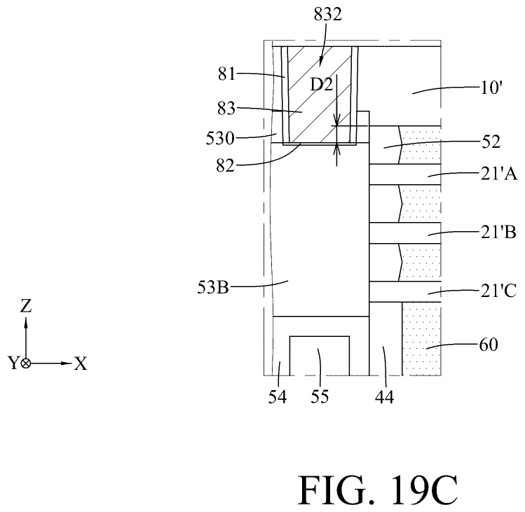

FIG. 1 is a flow diagram illustrating a method 100 for manufacturing the semiconductor structure (for example, the semiconductor structure shown in FIG. 19A) in accordance with some embodiments. FIGS. 2 to 19C illustrate schematic views of intermediate stages of the method in accordance with some embodiments. Some repeating structures are omitted in FIGS. 2 to 19C for the sake of brevity. Additional steps can be provided before, after or during the method, and some of the steps described herein may be replaced by other steps or be eliminated.

Referring to FIG. 1 and the examples illustrated in FIGS. 2 to 10, the method 100 begins at step 101, where devices (also known as semiconductor devices) are formed on a front side of a substrate 10.

Referring to FIG. 2, step 101 may include forming nanosheet stacks 20 respectively on fins 12 of the substrate 10.

In some embodiments, the nanosheet stacks 20 may be formed by: sequentially forming a nanosheet material stack (not shown) and a masking layer (not shown) on a starting substrate (not shown); patterning the masking layer into masking regions (not shown) using a patterned photoresist layer as a patterning mask; and patterning the nanosheet material stack into the nanosheet stacks 20 and patterning the starting substrate into the substrate 10 which includes the fins (or called protrusions, fin protrusions) 12 and a base 11 using the masking regions as a patterning mask. In some other embodiments, the masking layer is not formed, and the nanosheet material stack and the starting substrate are patterned using the patterned photoresist layer as a patterning mask.

The starting substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate may be doped with p-type impurities or n-type impurities, or undoped. In addition, the starting substrate may be a bulk silicon substrate, a silicon-on-insulator (SOI) substrate, or a germanium-on-insulator (GOI) substrate. In some embodiments, the starting substrate may be made of silicon. Other suitable materials for forming the starting substrate are within the contemplated scope of the present disclosure.

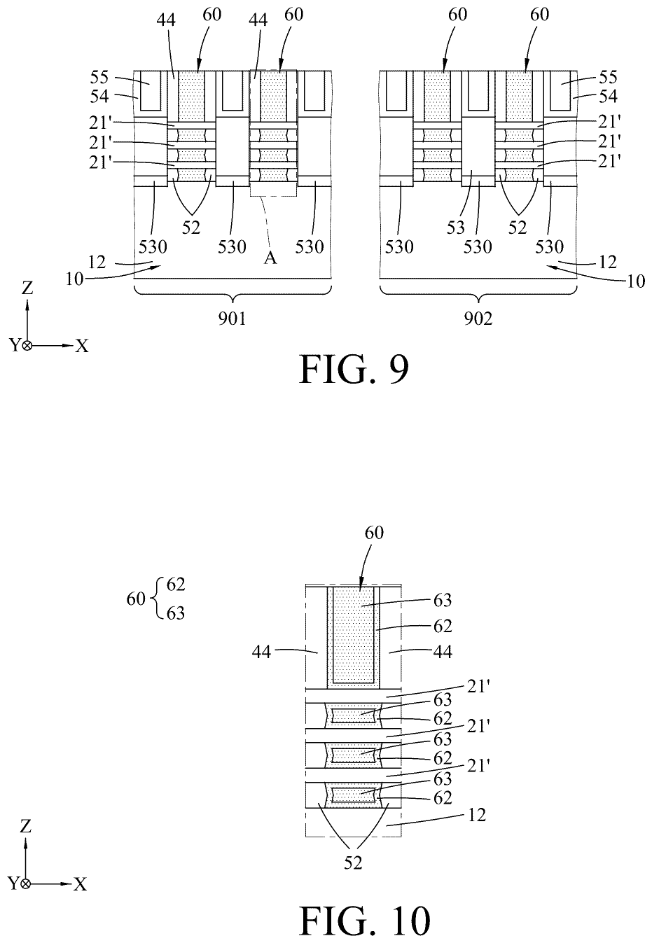

The nanosheet material stack includes first nanosheet layers (not shown); and second nanosheet layers (not shown) that are alternatively stacked on each other and that may be formed using any suitable deposition processes, such as physical vapor deposition (PVD), chemical vapor deposition (CVD), atomic layer deposition (ALD), or the likes, or combinations thereof, but are not limited thereto. In the following description, a deposition process, unless otherwise stated or defined in this disclosure, may be performed in a way similar to the above-mentioned ones. The first nanosheet layers are to be formed into channel layers 21 (see FIG. 2), and then channel features 21′ (see FIG. 9) of the devices. The second nanosheet layers are to be formed into sacrificial layers 22 (see FIG. 2) which will be removed in subsequent steps. The first nanosheet layers are made of a first semiconductor material, and the second nanosheet layers are made of a second semiconductor material different from the first semiconductor material. Possible materials for the first and second semiconductor materials are similar to those for the starting substrate, and thus details thereof are omitted for the sake of brevity. In some embodiments, the nanosheet material stack has three the first nanosheet layers, and three the second nanosheet layers, bur are not limited thereto. In certain embodiments, the first nanosheet layers include silicon, while the second nanosheet layers include silicon germanium. Other suitable processes, materials and/or numbers for each of the first and second nanosheet layers are within the contemplated scope of the present disclosure.

The patterning process (for forming the nanosheet stacks 20 and the substrate 10 as shown in FIG. 2) may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones. In some embodiments, after the patterning process, the masking regions may respectively remain on the nanosheet stacks 20.

As shown in FIG. 2, after the patterning process, the fins 12 of the substrate 10 are formed to be spaced apart from each other in a transverse direction (Y). Each of the fins 12 extends and is elongated in a longitudinal direction (X). The fins 12 are disposed on the base 11 of the substrate 10 in a vertical direction (Z). The transverse direction (Y), the longitudinal direction (X), and the vertical direction (Z) are traverse to (e.g., perpendicular to) each other.

Afterward, isolation elements 30 are formed on the base 11. The isolation elements 30 may be known as shallow trench isolations (STI). Specifically, each of the isolation elements 30 is formed on the base 11 between two adjacent ones of the fins 12. The isolation elements 30 may be formed by: depositing an isolation material for forming the isolation elements 30 using any suitable deposition processes such that the isolation material fills spaces among the nanosheet stacks 20; performing a planarization process (e.g., chemical mechanical polishing (CMP)) to obtain a planarized surface, through which the masking regions (not shown) remaining respectively on the nanosheet stacks 20 may be exposed; etching back the isolation material using any suitable etch-back processes, such as dry etching, wet etching, anisotropic etching, or combinations thereof; and removing the masking regions. In the following description, an etch-back process, unless otherwise stated or defined in this disclosure, may be performed in a way similar to the above-mentioned ones. In some embodiments, the isolation elements 30 include a dielectric material, such as an oxide-based dielectric (e.g., silicon oxide), but is not limited thereto. Other suitable processes, materials and/or configurations of the isolation elements 30 are within the contemplated scope of the present disclosure.

FIG. 2 is a perspective view of the semiconductor structure after forming the nanosheet stacks 20. As shown in FIG. 2, some of the nanosheet stacks 20 are located at a first region 901, in which the devices to be formed thereon are referred to as first devices; some of the nanosheet stacks 20 are located at a second region 902, in which the devices to be formed thereon are referred to as second devices. In some embodiments, the first region 901 is a logic region, and the first devices are logic devices; and the second region 902 is a memory region 902, and the second devices are memory devices. In accordance with some embodiments, the memory devices may be static random access memory (SRAM), but is not limited thereto. The logic region 901 and the memory region 902 may be connected to or be separated from each other according to product design of the semiconductor structure.

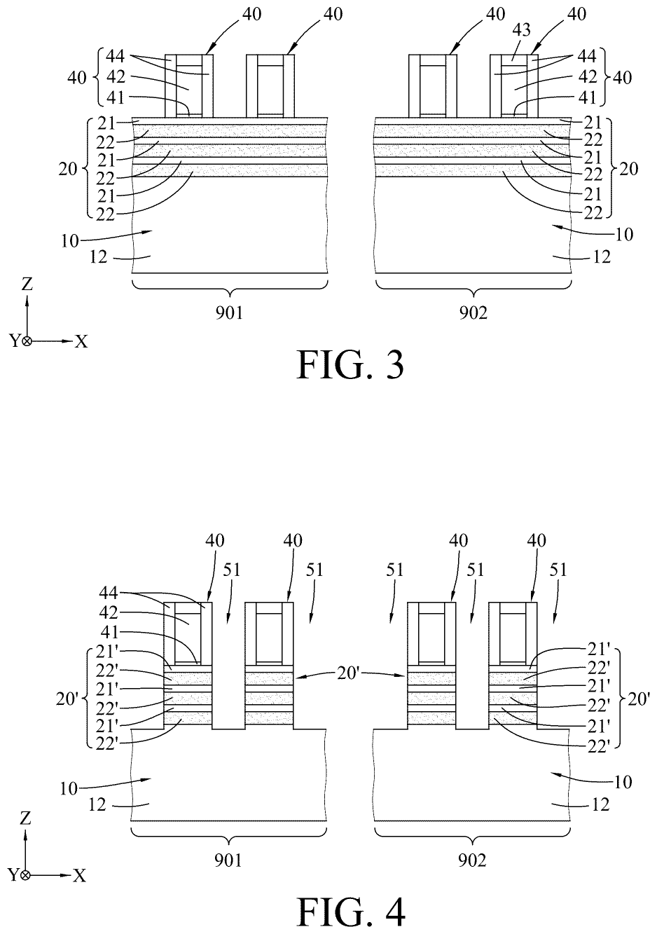

Referring to FIG. 3, step 101 may further include forming gate structures 40 over the nanosheet stacks 20. FIG. 3 is a cross-sectional view of the structure subsequent to the structure shown in FIG. 2 in accordance with some embodiments. In FIG. 3, a first portion of the structure (taken at one of the fins 12 at the logic region 901) along the longitudinal direction (X)) and a second portion of the structure (taken at one of the fins 12 at the memory region 902 along the longitudinal direction (X) are shown.

The gate structures 40 are spaced apart from each other in the longitudinal direction (X). Each of the gate structures 40 extends in the transverse direction (Y). Each of the gate structures 40 includes a dummy gate dielectric 41, a dummy gate electrode 42, and two gate spacers 44 that are respectively disposed on opposite sides of the dummy gate dielectric 41 and the dummy gate electrode 42 in the longitudinal direction (X). In each of the gate structures 40, the dummy gate dielectric 41 and the dummy gate electrode 42 cooperatively serve as a dummy gate. In addition, stack portions of each of the nanosheet stacks 20 are exposed from the gate structures 40.

Forming the gate structures 40 may include: depositing first and second dummy layers (not shown, respectively for forming the dummy gate dielectric 41 and the dummy gate electrode 42) using any suitable deposition processes; performing a planarization process (e.g., CMP) to obtain a planar upper surface of the second dummy layer (i.e., a planarized second dummy layer) distal from the fins 12; forming a third dummy layer (not shown, for forming masks 43) on the planarized second dummy layer using any suitable deposition processes; and patterning the first dummy layer, the planarized second dummy layer and the third dummy layer to partially expose the fins 12 and the isolation elements 30 (not shown in FIG. 3) using any suitable patterning processes and/or etching processes, such that the dummy gate dielectrics 41 and the dummy gate electrodes 42 of the gate structures 40 are obtained with the masks 43 respectively disposed thereon; depositing a spacer material layer (not shown, for forming gate spacers 44 using any suitable deposition processes; and patterning the spacer material layer by any suitable patterning processes and/or etching processes, such that the gate spacers 44 of each of the gate structures 40 are obtained. Other suitable processes for forming the gate structures 40 and the masks 43 are within the contemplated scope of the present disclosure. The dummy gate dielectric 41 may include a dielectric material, such as silicon oxide, or the likes. The dummy gate electrode 42 may include polycrystalline silicon, or the likes. The masks 43 may be each a single layer structure, or a multi-layered structure. The masks 43 may include a dielectric material, such as silicon nitride, silicon oxide, silicon oxynitride, or the likes, or combinations thereof. The gate spacers 44 may be made of one or more materials, and may include a dielectric material, such as a silicon carbon-containing dielectric material, a silicon oxide-containing material, silicon nitride, other suitable materials, or combinations thereof. Other suitable materials for each of the dummy gate dielectric 41, the dummy gate electrode 42, the masks 43, and the gate spacers 44 are within the contemplated scope of the present disclosure.

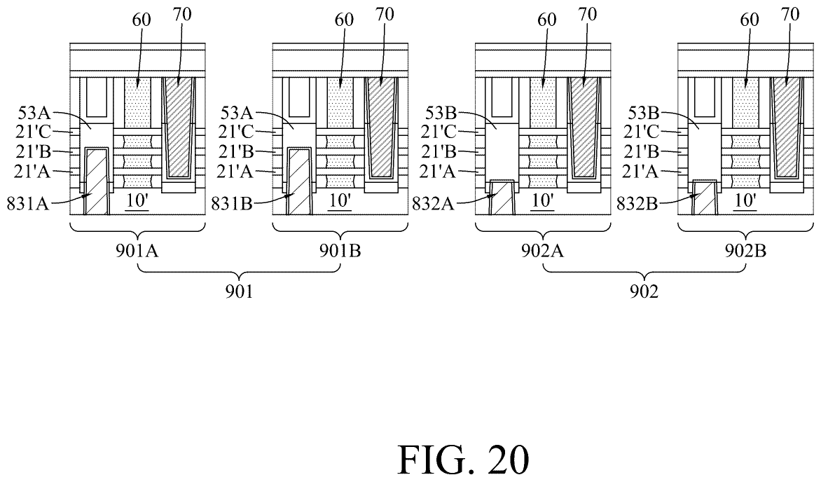

In some embodiments, forming the gate structures 40 may also include forming fin sidewall layers (not shown) that cover the stack portions of the nanosheet stacks 20. The gate spacers 44 and the fin sidewall layers may be made of a same or different material in a same or different processes. The fin sidewall layers may be formed into fin sidewalls 45 (see FIG. 20) in subsequent processes.

Referring to FIG. 4, step 101 may further include forming source/drain recesses 51.

The source/drain recess 51 may be formed by: patterning each of the nanosheet stacks 20 (see FIG. 3) into a plurality of stack segments 20′, thereby removing the stack portions of each of the nanosheet stacks 20, and obtaining the source/drain recesses 51. The patterning process may include, as described in the foregoing, a photolithography process, followed by an etching process. The stack segments 20′ are spaced apart from each other in the longitudinal direction (X). In some embodiments, the source/drain recesses 51 formed by patterning each of the nanosheet stacks 20 are further extended into a respective one of the fins 12. The channel layers 21 (see FIG. 3) are formed into channel features 21′ and the sacrificial layers 22 are formed into sacrificial features 22′. Other suitable processes for forming the source/drain recesses 51 are within the contemplated scope of the present disclosure. As such, a plurality of channel portions are obtained, and each of the channel portions includes the channel features 21′ of a respective one of the stack segments 20′.

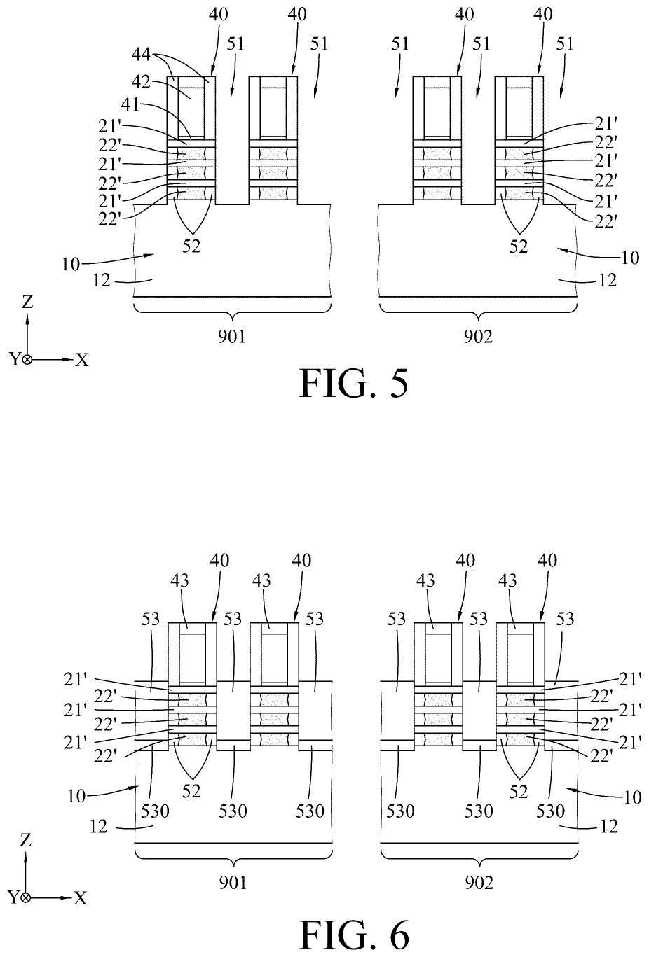

Referring to FIG. 5, step 101 may further include forming inner spacers 52.

The inner spacers 52 may be formed by: removing end regions of each of the sacrificial features 22′ that are opposite to each other in the longitudinal direction (X) and that are respectively located beneath the gate spacers 44 of a corresponding one of the gate structures 40 using any suitable patterning processes, etching processes, and or etch-back processes; and forming the inner spacers 52 at two opposite sides of each of the remaining sacrificial features 22′ in the longitudinal direction (X). The inner spacers 52 may include a dielectric material such as silicon oxide, silicon nitride, silicon oxynitride, silicon carbide, or the likes, or combinations thereof. Other suitable materials and/or processes for forming the inner spacers 52 are within the contemplated scope of the present disclosure.

Referring to FIG. 6, step 101 may further include forming source/drain portions 53 respectively in the source/drain recesses 51 (see FIG. 5).

In some embodiments, the base epitaxial layers (not shown) are first formed in bottoms of the source/drain recesses 51, respectively. The base epitaxial layers may include silicon, or other suitable semiconductor material. The base epitaxial layers may be undoped, but is not limited thereto. Other suitable materials for forming the base epitaxial layers are within the contemplated scope of the present disclosure.

In some embodiments, bottom isolation elements 530 are then formed on the base epitaxial layers, respectively. The bottom isolation elements 530 may be made of a dielectric material, for example, but not limited to, silicon nitride (SiN), silicon oxide (SiO), silicon oxynitride (SiON), silicon carbon nitride (SiCN), silicon carbon oxynitride (SiCON), silicon oxycarbide (SiCO), a high-k material (e.g., aluminum oxide, hafnium oxide, hafnium silicates, hafnium silicon oxynitride, tantalum-doped hafnium oxide, hafnium titanate, zirconium-doped hafnium oxide, and the like), or combinations thereof. In some embodiments, the bottom isolation elements 530 may be formed by a suitable deposition process, for example, but not limited to, CVD or ALD. Other suitable materials and/or processes for forming the bottom isolation elements 530 are within the contemplated scope of the present disclosure.

The source/drain portions 53 are respectively formed on the bottom isolation elements 530. The source/drain portions 53 may be formed using e.g., an epitaxy growth process, but is not limited thereto. In some embodiments, the source/drain portions 53 may include single or multiple epitaxy layers. In certain embodiments, the source/drain portions 53 may include silicon, silicon germanium, other suitable materials, or combinations thereof. In other embodiments, the source/drain portions 53 may include any suitable dopants. For instance, when the devices are designed to be n-type devices, the source/drain portions 53 may be doped with n-type dopant(s). In contrast, when the devices are designed to be p-type devices, the source/drain portions 53 may be doped with p-type dopant(s). Other suitable materials and/or processes for forming the source/drain portions 53 are within the contemplated scope of the present disclosure. The channel features 21′ are each connected to two corresponding adjacent ones of the source/drain portions 53.

Please note that each of the source/drain portions 53 has a proximal surface and a distal surface that are opposite to each other and that are respectively proximal to and distal from the substrate 10.

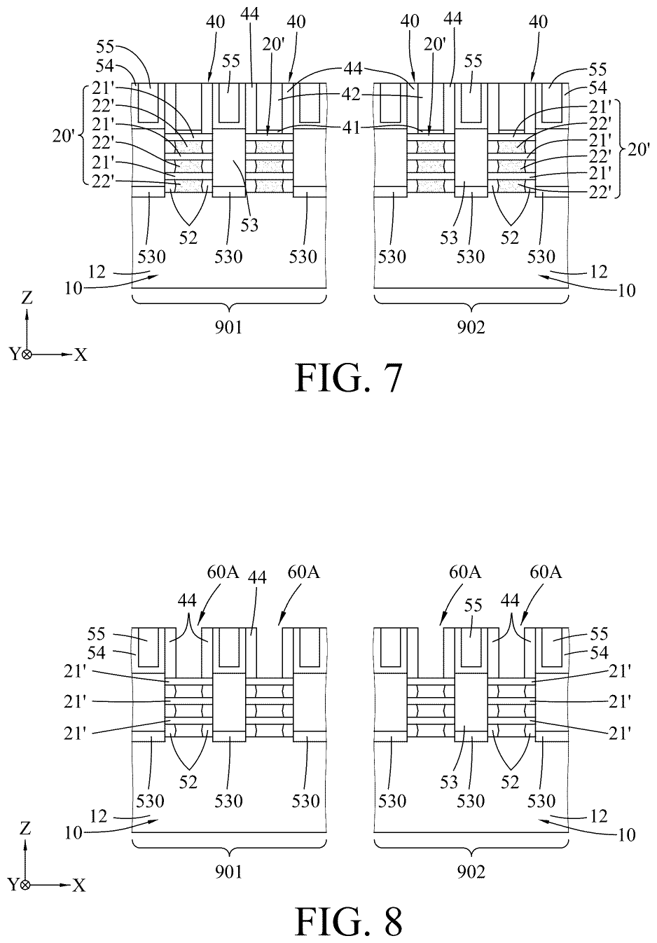

Referring to FIG. 7, step 101 may further include forming contact etch stop layers (CESLs) 54 and interlayer dielectrics (ILDs) 55 over the source/drain portions 53, and the isolation elements 30 (not shown in FIG. 7).

The CESLs 54 and the ILDs 55 may be formed by: sequentially depositing two dielectric material layers respectively for forming the CESLs 54 and the ILDs 55 over the structure shown in FIG. 6 using any suitable disposition processes, followed by removing an excess of the two dielectric material layers using a planarization process (e.g., CMP). Accordingly, the masks 43 are also removed to expose the dummy gate electrodes 42 of the gate structures 40 therebeneath. Each of the CESLs 54 and the ILDs 55 may include a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or the like, or combinations thereof. The CESLs 54 and the ILDs 55 may include different dielectric materials. Other suitable materials and processes for forming the CESLs 54 and the ILDs 55 are within the contemplated scope of the present disclosure. As shown in FIG. 7, each of the CESLs 54 and a corresponding one of the ILDs 55 are formed over a corresponding one of the source/drain portions 53 between the gate spacers 44 of two adjacent ones of the gate structures 40.

Referring to FIG. 8, step 101 may further include removing the dummy gates (i.e., the dummy gate dielectrics 41 and the dummy gate electrodes 42 of the gate structures 40, see FIG. 7) and the remaining sacrificial layers 22′ of the nanosheet stacks 20′, so as to form cavities 60A that accommodate active gates 60 formed in subsequent step.

The dummy gates of the gate structures 40 and the remaining sacrificial features 22′ of the nanosheet stacks 20′ may be removed using any suitable etching processes. Other suitable processes for removing the dummy gates and the remaining sacrificial features 22′ are within the contemplated scope of the present disclosure.

Referring to FIGS. 9 and 10, step 101 may further include forming active gates 60 respectively in the cavities 60A. FIG. 10 is an enlarged view of a portion of the structure that is labeled as region A as shown in FIG. 9 in accordance with some embodiments. Each of the active gates 60 includes an active gate electrode 63, and an active gate dielectric 62 surrounding the active gate electrode 63.

Forming the active gates 60 may include: forming interfacial layers (not shown) respectively around the channel features 21′ and over the fins 12; forming the active gate dielectrics 62 of the active gates over the interfacial layers, the isolation elements 30 (not shown in FIGS. 9 and 10) and the gate spacers 44; forming active gate electrodes 63 over the active gate dielectrics 62 and filling the cavities 60A; and performing a planarization process (e.g., CMP) to expose the CESLs 54 and the ILDs 55. The interfacial layers may include a dielectric material such as silicon oxide, silicon nitride, silicon oxynitride, or combinations thereof, but is not limited thereto. The active gate dielectrics 62 may include a high dielectric constant material, such as a hafnium-based dielectric material, or the like, but is not limited thereto. The active gate electrodes 63 may include a conductive material such as a metal, a metal-containing nitride, a metal-containing silicide, a metal-containing carbide, or the likes, but are not limited thereto. Other suitable materials and/or methods for forming the interfacial layers and/or the active gates 60 are within the contemplated scope of the present disclosure.

By completing the processes described in FIGS. 2 to 10, step 101 is completed, and the devices are formed on the front side of the substrate 10 (one of the fins 12 of the substrate 10 is shown in FIG. 9). Each of the devices includes a corresponding one of the active gates 60, two corresponding ones of the source/drain portions 53, and corresponding ones of the channel features 21′ that interconnect the two corresponding source/drain portions 53. In some embodiments, in each of the devices, a first one of the two corresponding source/drain portions 53 is connected to a back power routing through a corresponding back side via (which will be formed in step 105) and serves as a source of the device; while a second one of the two corresponding source/drain portions 53 is connected to the first one of the source/drain portion 53 through the corresponding channel features 21′, and serve as a drain of the device. In the exemplary embodiment, each of the devices is a gate-all-around type of nanosheet device, but is not limited thereto. In other embodiments, the devices may also be other suitable devices, such as planar devices, forsksheet type devices, fin field-effect transistors, complementary field-effect transistors, or the likes, or combinations thereof, but are not limited thereto. Please note that the logic devices (i.e., the devices formed at the logic region 901) and the memory devices (i.e., the devices formed at the memory region 902) may be formed at the same (or different) time and with the same (or different) parameters, based on practical needs or product design. For instance, in accordance with some embodiments, a fin width (measured in the transverse direction (Y)) of n-type memory devices may be different form a fin width of p-type memory devices. In some embodiments, n-type memory devices may be formed with a fin width that is about 5 nm to about 40 nm larger than a fin width of n-type logic devices. In other embodiments, p-type memory devices may be formed with a fin width that is about 5 nm to about 40 nm smaller than a fin width of p-type logic devices. In certain embodiments, memory devices may have a cell height that is about 10 nm to about 100 nm larger than a cell height of logic devices.

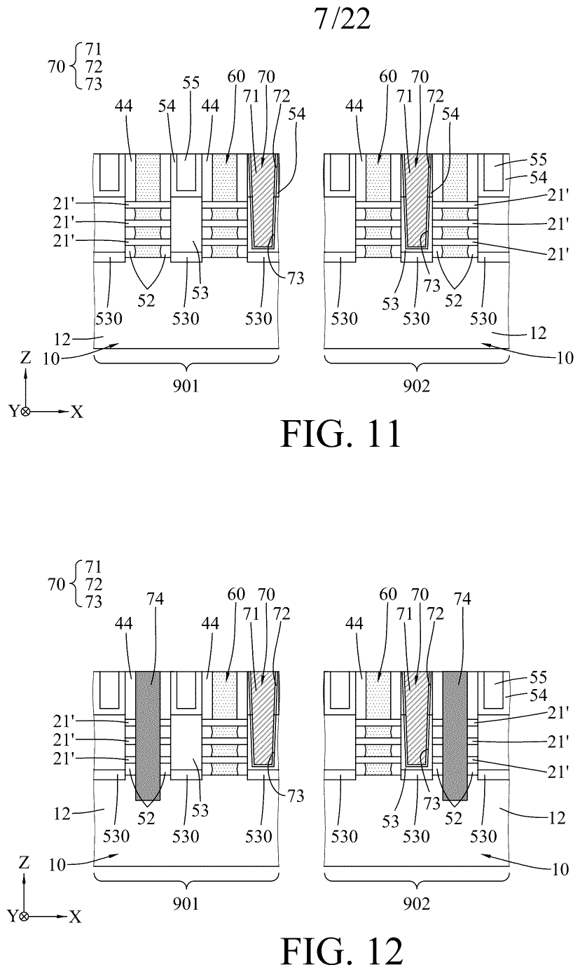

Referring to FIG. 1 and the example illustrated in FIG. 11, the method proceeds to step 102, where source/drain contacts 70 are formed.

The source/drain contacts 70 are respectively connected to predetermined ones of the source/drain portions 53 from front sides of the devices, and may be known as a type of front side contacts of the semiconductor structure. In some embodiments, each of the source/drain contacts 70 extends from a corresponding one of the CESLs 54 and a corresponding one of the ILDs 55 and terminates at (or within) a corresponding one of the source/drain portions 53. Each of the source/drain contacts 70 includes a contact body 71, an insulating layer 72, and a silicide layer 73. The contact body 71 has a first section that is located within the corresponding source/drain portion 53, and a second section that extends away from the first section into the corresponding CESL 54 and the corresponding ILD 55. The insulating layer 72 is formed to surround the second section of the contact body 71 (and terminates at the corresponding source/drain portion 53). The silicide layer 73 is formed to surround the first section of the contact body 71. In some embodiments, the insulating layer 72 and/or the silicide layer 73 may be omitted according to practical needs.

The source/drain contacts 70 may be formed by: performing a patterning process to form shallow contact trenches (not shown), each of which extends from the corresponding CESL 54 and the corresponding ILD 55 to expose the distal surface (distal from the fin 12) of the corresponding source/drain portion 53; selectively forming the insulating layer 72 (of each of the source/drain contacts 70) on sidewall of each of the shallow contact trenches; performing another patterning process through the shallow contact trenches to form the shallow contact trenches into deep contact trenches (not shown), each of which extends from the distal surface into interior of the corresponding source/drain portion 53 (toward the fin 12); forming the silicide layer 73 (of each of the source/drain contacts 70) on sidewall of each of the deep contact trenches beneath the corresponding insulating layer 72 using a silicidation process (but is not limited thereto); and filling the deep contact trenches with a contact body material (for forming the contact body 71 of each of the source/drain contacts 70); and performing a planarization process (e.g., CMP, but is not limited thereto), so as to obtain the source/drain contacts 70. In some embodiments, the contact body 71 may include a conductive material such as tungsten (W), aluminum (Al), ruthenium (Ru), cobalt (Co), copper (Cu), palladium (Pd), nickel (Ni), platinum (Pt), a low resistivity metal constituent, or the likes, or combinations thereof. In some embodiments, the insulating layer 72 may include an insulating material, such as a dielectric material like silicon nitride, but is not limited thereto. In some embodiments, the silicide layer 73 may include titanium silicide, ruthenium silicide, nickel silicide, cobalt silicide, molybdenum silicide, or the likes, or combinations thereof. Other suitable materials and/or processes for forming the source/drain contacts 70 are within the contemplated scope of the present disclosure.

Referring to FIG. 12, after forming the source/drain contacts 70, in some embodiments, isolation features 74 may be formed using a continuous poly on diffusion edge (CPODE, or CPD) process. The isolation features 74 may be formed by: performing a patterning process (using e.g., any suitable etching process) to remove predetermined ones of the active gates 60 and corresponding ones of the channel features 21′ that are surrounded by the predetermined active gates 60, until front portions of the fin 12 beneath the predetermined active gates 60 are partially removed so as to form isolation trenches (not shown); performing a depositing process to deposit a dielectric material for forming the isolation features 74 to fill the isolation trenches; and performing a planarization process (e.g., CMP, but is not limited thereto) to remove any excess amount of the dielectric material, so as to form the isolation features 74. In some embodiments, the dielectric material may include silicon oxide, silicon oxycarbide, silicon nitride, or the likes, or combinations thereof, but are not limited thereto. Other suitable materials and/or processes for forming the isolation features 74 are within the contemplated scope of the present disclosure. After step 102, a front-end-of-line (FEOL) portion of the semiconductor structure is obtained.

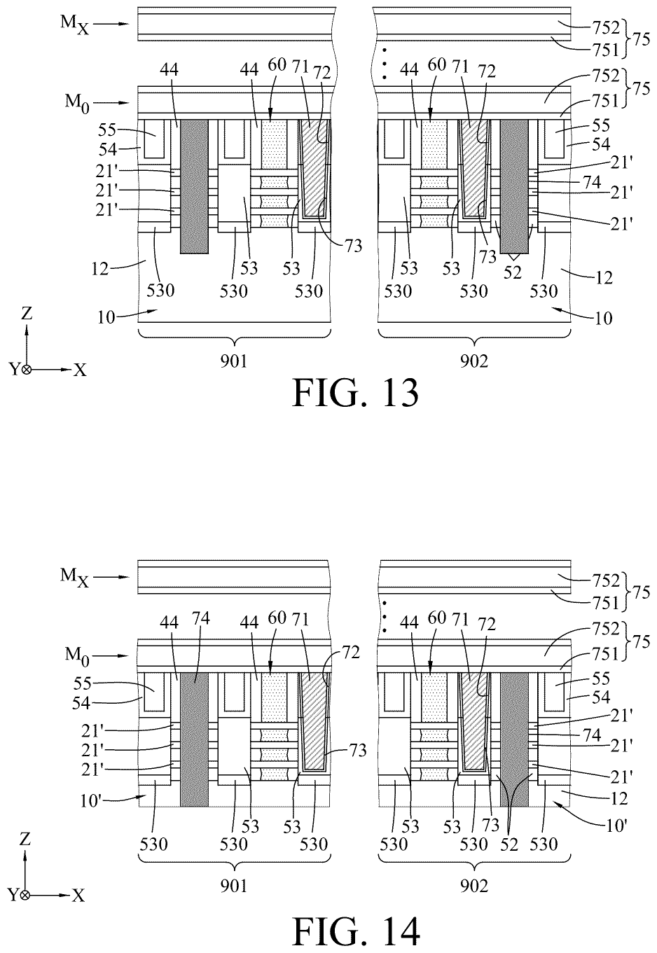

Referring to FIG. 1 and the example illustrated in FIG. 13, the method 100 proceeds to step 103, where a back-end-of-line (BEOL) portion is formed.

The BEOL portion is formed on the FEOL portion, or more specifically on the devices opposite to the fin 12. The BEOL portion may include interconnect levels (e.g., M₀, Mₓ as shown in FIG. 13) that are stacked on each other in the vertical direction (Z). Each of the interconnect levels includes a dielectric portion 75 and conduction portion(s) 76 (see FIG. 30) formed in the dielectric portion 75. In certain embodiments, the dielectric portion 75 includes a low-k dielectric material. In some embodiments, the dielectric portion 75 may include an etch stop layer 751 and an intermetallic dielectric (IMD) layer 752 which are made of different dielectric materials, such as silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. In some embodiments, the conductive portion(s) 76 may be configured as conductive lines or conductive vias, each of which is connected to the active gate electrode 63 (see FIG. 10) of a corresponding one of the active gates 60 or a corresponding one of the source/drain portions 53. The materials for conductive portion(s) 76 may be similar to those for forming the contact body 71 of each of the source/drain contacts 70, and the interconnect levels may be formed using any suitable damascence processes. Other suitable materials and processes for forming the interconnect levels are within the contemplated scope of the present disclosure.

Referring to FIG. 1 and the example illustrated in FIG. 14, the method 100 proceeds to step 104, where the substrate 10 is thinned down from a back side thereof. In step 104, the substrate 10 is subjected to a polishing process (for example, CMP, but is not limited thereto), an etching process or combinations thereof, such that the substrate 10 has a reduced thickness, as denoted by the numeral 10′.

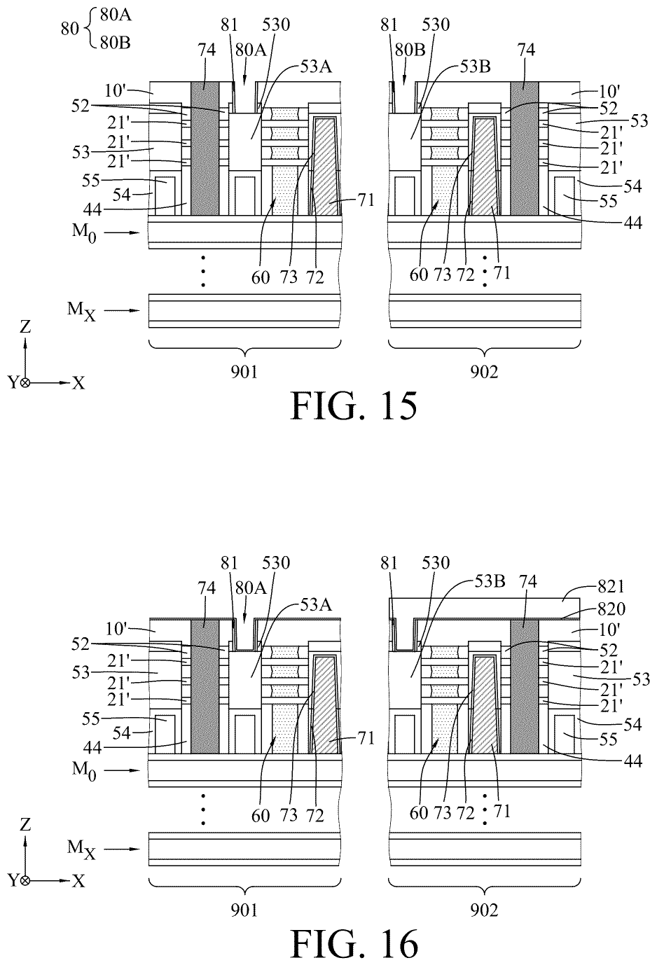

Referring to FIG. 1 and the examples illustrated in FIGS. 15 to 19C, the method 100 proceeds to step 105, wherein back side vias including first vias and second vias, are formed on back side of the devices as shown in FIG. 19A. The first vias may be referred to as logic vias 831 (one of which is shown) and the second vias may be referred to as memory vias 832 (one of which is shown). Each of the logic vias 831 penetrates through the substrate 10′, extends from a back side of a respective one of the logic devices and is connected to the source/drain portion 53A of the respective logic device. Each of the memory vias 832 penetrates through the substrate 10′, extends from a back side of a respective one of the memory devices, and is connected to the source/drain portion 53B of the respective memory device. Please note that the structures shown in FIGS. 15 to 19A are structures subsequent to that shown in FIG. 14, in which the structures in FIGS. 15 to 19A are turned upside down (in the vertical direction (Z)) in comparison with the structure shown in FIG. 14 for easy illustration.

Referring to FIG. 15, step 105 may include performing a first patterning process to form shallow trenches 80, each of which extends through the substrate 10′ to terminate at the proximal surface of a corresponding one of predetermined source/drain portions 53. The patterning process may adopt any suitable processes, such as an etching process, but is not limited thereto.

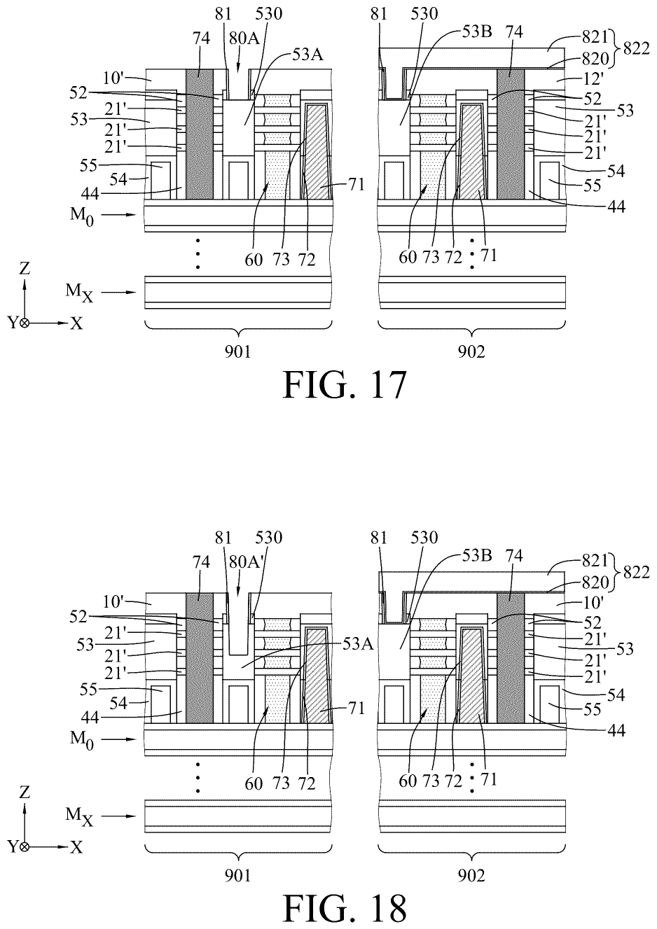

Specifically, there are two types of shallow trenches 80, namely first shallow trenches and second shallow trenches. The first shallow trenches may be referred to as logic shallow trenches 80A. The second shallow trenches may be referred to as memory shallow trenches 80B. The logic shallow trenches 80A and the memory shallow trenches 80B are formed in the logic devices at the logic region 901 and in the memory devices at the memory region 902, respectively. In FIG. 17, only one of the logic shallow trenches 80A and one of the memory shallow trenches 80B are shown, and in following paragraphs, each of the logic shallow trenches 80A and the memory shallow trenches 80B are illustrated in singular form for easy understanding. The logic shallow trench 80A penetrates through the substrate 10′ and a corresponding one of the bottom isolation elements 530, and terminates at the proximal surface of a corresponding source/drain portion which is labeled 53A. The memory shallow trench 80B penetrates through the substrate 10′ and a corresponding one of the isolation elements 530, and terminates at the proximal surface of a corresponding source/drain portion which is labeled 53B.

Afterward, an insulating layer 81 may be formed selectively on sidewall of each of the logic shallow trench 80A and the memory shallow trench 80B, so that the proximal surface of each of the source/drain portions 53A, 53B is exposed. The insulating layer 81 may be formed by conformally depositing a dielectric material over the substrate 10′, the logic shallow trench 80A and the memory shallow trench 80B, and the exposed ones of the source/drain portions 53A, 53B, followed by performing a selective etching process to remove portions of the dielectric material that are disposed on surfaces of the structure that are laid in the longitudinal direction (X). The dielectric material may be similar to or different from the material of the insulating layer 72 as described in FIG. 11, and thus details thereof are omitted for the sake of brevity. Other suitable processes and materials for forming the insulating layer 81 are within the contemplated scope of the present disclosure.

Referring to FIGS. 16 and 17, step 105 may further include forming a mask 822 to cover the memory shallow trench 80B (see FIG. 15), and to expose the logic shallow trench 80A.

Forming the mask 822 may include: as shown in FIG. 16, forming a hard mask layer 820 over the structure shown in FIG. 15 to cover both the logic region 901 and the memory region 902; forming a patterned photoresist layer 821 over the memory region 902; and as shown in FIG. 17, removing a portion of the hard mask layer 820 that is located at the logic region 901, thereby forming the mask 822 at the memory region 902 to cover the memory shallow trench 80B, while the logic shallow trench 80A is exposed from the mask 822.

Referring to FIG. 18, step 105 may further include performing a second patterning process to form the logic shallow trench 80A (see FIG. 17) into a logic deep trench 80A′ (also known as a first deep trench). The second patterning process may adopt any suitable patterning process, such as an etching process, but is not limited thereto. The logic deep trench 80A′ further penetrates into the source/drain portion 53A, and terminates in an interior of the source/drain portion 53A. By controlling parameters of the second patterning process, depth of the logic deep trench 80A′ may be varied according to practical needs and product design.

After forming the logic deep trench 80A′ as shown in FIG. 18, the mask 822 covering the memory shallow trench 80B may be removed. As such, the source/drain portion 53A and the source/drain portion 53B are exposed from the logic deep trench 80A′ and the memory shallow trench 80B (see FIG. 15), respectively. In addition, it is noted that the logic deep trench 80A′ and the memory shallow trench 80B are formed with different depths.

Referring to FIGS. 19A, 19B and 19C, step 105 may further include forming a logic via 831 and a memory via 832 in the logic deep trench 80A′ (see FIG. 18) and the memory shallow trench 80B (see FIG. 15), respectively. FIGS. 19B and 19C are partially enlarged views of regions B and C labeled in FIG. 19A, respectively.

Each of the logic via 831 and the memory via 832 includes the insulating layer 81, a silicide layer 82 and a via body 83.

Forming the logic via 831 and the memory via 832 may include: forming the silicide layer 82 on sidewall of each of the logic deep trench 80A′ and the memory shallow trench 80B beneath the corresponding insulating layer 81 (using, e.g., a silicidation process, but is not limited thereto); depositing a via material (for forming the via body 83) over the logic deep trench 80A′ and the memory shallow trench 80B; and a planarization process (e.g., CMP, but is not limited thereto), so as to obtain the logic via 831 and the memory via 832. The via material may be similar to the conductive material for forming the contact body 71 as described in step 102, and thus is not repeated for the sake of brevity. Other suitable materials for forming the logic via 831 and the memory via 832 are within the contemplated scope of the present disclosure. In some other embodiments, the logic via 831 and the memory via 832 may also be formed with different via materials.

The logic via 831 and the memory via 832 are thus formed. In some embodiments, the insulation layer 81 is formed between the substrate 10′ and a respective one of the logic via 831 and the memory via 832. In certain embodiments, the silicide layer 82 is formed between the via body 83 and a respective one of the source/drain portions 53A, 53B. As shown in FIGS. 19A and 19B, the logic via 831 has a first section that is located within the source/drain portion 53A of the logic device, and a second section that extends away from the first section into the substrate 10′. The insulating layer 81 may be formed around the second section. The silicide layer 82 may be formed around the first section. Please note that in other embodiments, the memory via 832 may also penetrate into the source/drain portion 53B of the memory device, and thus have aforementioned configuration. In some embodiments, the insulating layer 81 and/or the silicide layer 82 may be omitted according to practical needs.

After completing step 105, the semiconductor structure of the present disclosure obtained. In some embodiments, the back side vias, i.e., the logic via 831 and the memory via 832, may be configured to connect the logic device and the memory device to e.g., a power supply (but is not limited thereto) from back sides of the logic device and the memory device, respectively. Other suitable utilization/connection of the back side vias 831, 832 are within the contemplated scope of the present disclosure. In some embodiments, the back side vias 831, 832 may each protrude from the isolation elements 30 (see FIG. 2) by a distance ranging from about 15 nm to about 30 nm, but is not limited thereto.

As shown in FIGS. 19B and 19C, the three channel features 21′ in each of the channel portions may be also referred as a proximal channel feature 21′A (proximal to the substrate 10′), a middle channel feature 21′B, and a distal channel feature 21′C (distal from the substrate 10′), respectively. The proximal channel feature 21′A may be referred to as a bottommost one of the channel features 21′ of the corresponding device. It is noted that the logic via 831 and the memory via 832 are formed with different depths. As shown in FIGS. 19B and 19C, each of the logic via 831 and the memory via 832 has a portion that penetrates into a stack including the source/drain portion 53A, 53B and the bottom isolation element 530 connected thereto. The logic via 831 extends over the substrate 10′ by a first depth (D1), while the memory via 832 extends over the substrate 10′ by a second depth (D2). In some embodiments, the first depth (D1) is greater than the second depth (D2) by not less than approximately 2 nm, such as ranging from about 2 nm to about 25 nm, e.g., from about 2 nm to about 10 nm, from about 5 nm to about 15 nm, from about 10 nm to about 20 nm, or from about 15 nm to about 25 nm, but is not limited thereto. Such range permits the logic devices and the memory devices to have optimized performance. In certain embodiments, the first depth (D1) is greater than the second depth (D2) by at least a height (a distance measured along the vertical direction (Z)) of each of the channel features 21′A, 21′B, 21′C. In certain embodiments, a volume of the logic via 831 is greater than a volume of the memory via 832.

The aforesaid configurations of the logic via 831 and the memory via 832 are advantageous in various aspects. It is desirable that a contact resistance level between the logic via 831 and the source/drain portion 53A is as low as possible, so as to enhance performance of the logic device. As such, the logic via 831 is formed with a relatively large first depth (D1), and thus has a relatively large volume, which is conducive to minimizing the contact resistance level of the logic via 831. On the other hand, it is desirable that a current leakage between the memory via 832 and the inner spacers 52 of the corresponding memory device, and/or a current leakage between the memory via 832 and the active gate electrode 63 (see FIG. 10, especially a portion of the active gate electrode 63 that is located above the channel features 21′) of the corresponding memory device is as low as possible. As such, the memory via 832 is formed with a relatively small second depth (D2), and thus has a relatively small volume, which is conducive to minimizing the leakage current between the memory via 832 and the inner spacers 52, or the active gate electrode 63.

Each of the logic via 831 and the memory via 832 has a proximal surface and a distal surface that are opposite to each other, and that are respectively proximal and distal relative to the substrate 10′. In some embodiments, a first distance (i.e., D1) between the substrate 10′ and the distal surface of the logic via 831 is larger than a second distance (i.e., D2) between the substrate 10′ and the distal surface of the memory via 832.

In some embodiments, the first distance is larger than a third distance, which is a distance between the substrate 10′ and the proximal channel feature 21′A of the corresponding device. In other embodiments, the second distance is less than the third distance.

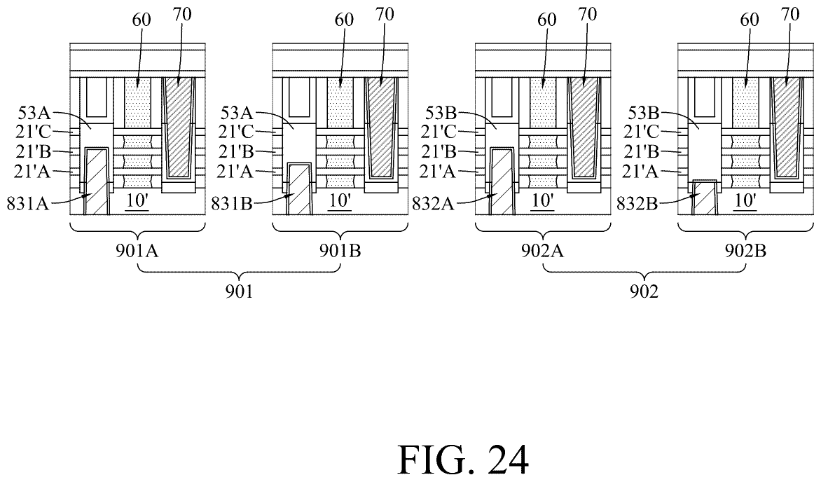

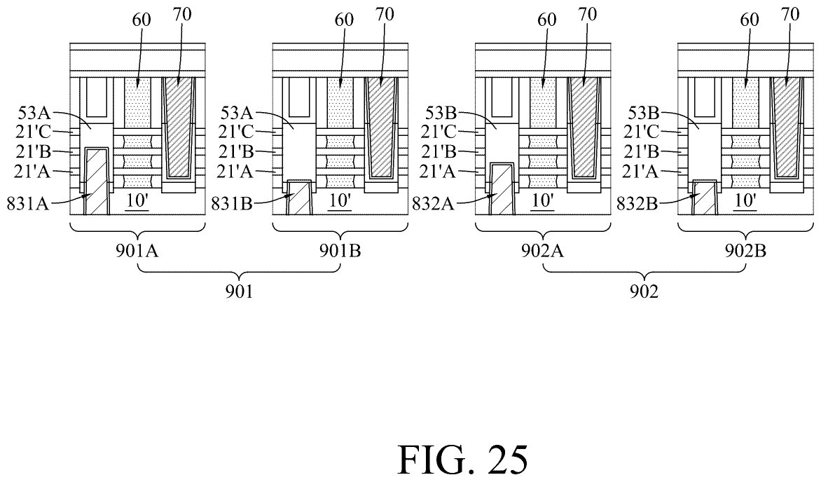

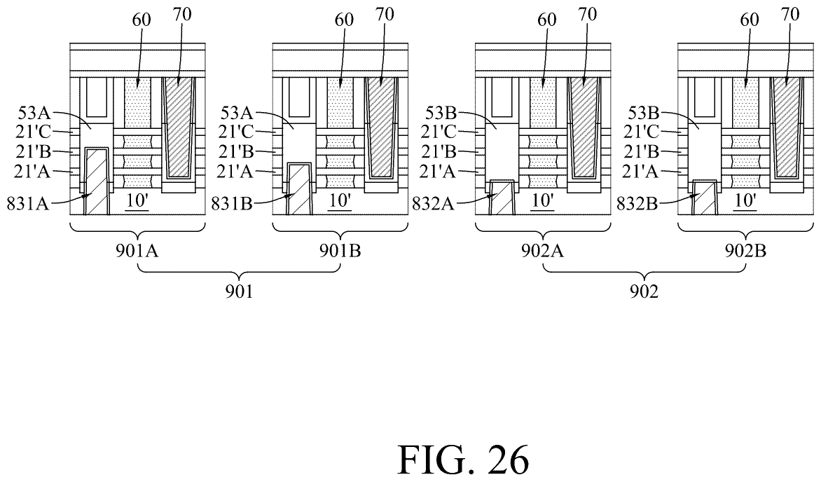

In some embodiments, the devices may be formed to have different types of conductivity. For devices having the same type of conductivity, a back side via of a logic device has a depth that is larger than a depth of a back via of a memory device. For instance, FIGS. 20 to 26 illustrate a series of alternative configurations for the logic devices 901A, 901B, the memory devices 902A, 902B, the logic vias 831A, 831B, the memory vias 832A, 832B in accordance with some embodiments. At the logic region 901, the logic devices may include n-type logic devices 901A and p-type logic devices 901B; while the logic vias 831 (one of which is shown in FIG. 19A) may include first logic vias 831A that are respectively connected to the n-type logic devices 901A, and second logic vias 831B that are respectively connected to the p-type logic devices 901B. The first logic vias 831A may be referred to as first vias of the first device vias. The second logic vias 831B may be referred to as second vias of the first device vias. At the memory region 902, the memory devices may include n-type memory devices 902A and p-type memory devices 902B; while the memory vias 832 (one of which is shown in FIG. 19A) may include first memory vias 832A that are respectively connected to the n-type memory devices 902A, and second memory vias 832B that are respectively connected to the p-type memory devices 902B. The first memory vias 832A may be referred to as first vias of the second device vias. The second memory vias 832B may be referred to as second vias of the second device vias. In some embodiments, a depth of the first logic via 831A is greater than a depth of the first memory via 832A (see FIGS. 20, 21, 23, 25 and 26). That is, a volume of the first logic via 831A is greater than a volume of the first memory via 832A. In other embodiments, a depth of the second logic via 831B is greater than a depth of the second memory vias 832B (see FIGS. 20, 22, 23, 24 and 26). That is, a volume of the second logic via 831B is greater than a volume of the second memory via 832B.

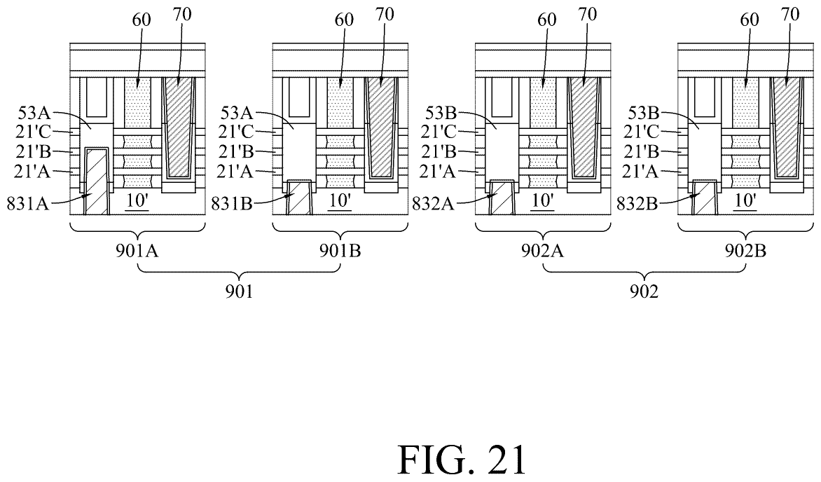

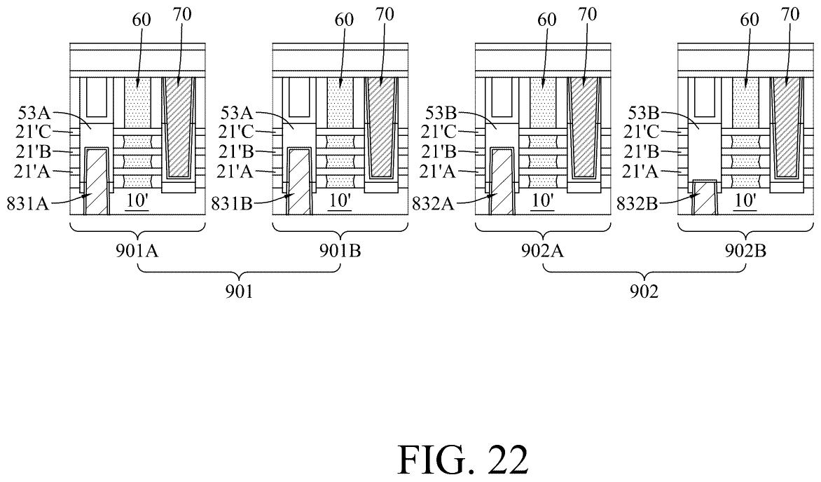

In some embodiments, for the same devices (i.e., for the logic devices or the memory devices), a back side via of an n-type device has a depth greater than a depth of a back side via of a p-type device. As exemplarily shown in FIG. 27, which illustrates a cross-sectional view of the source/drain portions 53 of one n-type logic device 901A and one p-type logic device 901B, a depth of the first logic via 831A is greater than a depth of the second logic via 831B (see also FIGS. 21, 23, 24, 25 and 26) by about 2 nm to about 10 nm, but is not limited thereto. That is, a volume of the first logic via 831A is greater than a volume of the second logic vias 831B. In other embodiments, a depth of the first memory via 832A is greater than a depth of the second memory via 832B (see also FIGS. 22, 23, 24 and 25) by about 2 nm to about 10 nm, but is not limited thereto. That is, a volume of the first memory via 832A is greater than a volume of the second memory via 832B. The aforesaid configurations are advantageous in permitting the source/drain portions 53 of the p-type devices to have a relatively large volume (in comparison with the source/drain portions 53 of the n-type devices), so that a sufficient amount of compressive stress in the longitudinal direction (X) can be induced in the channel features 21′ of the p-type devices, thereby enhancing performance of the p-type devices.

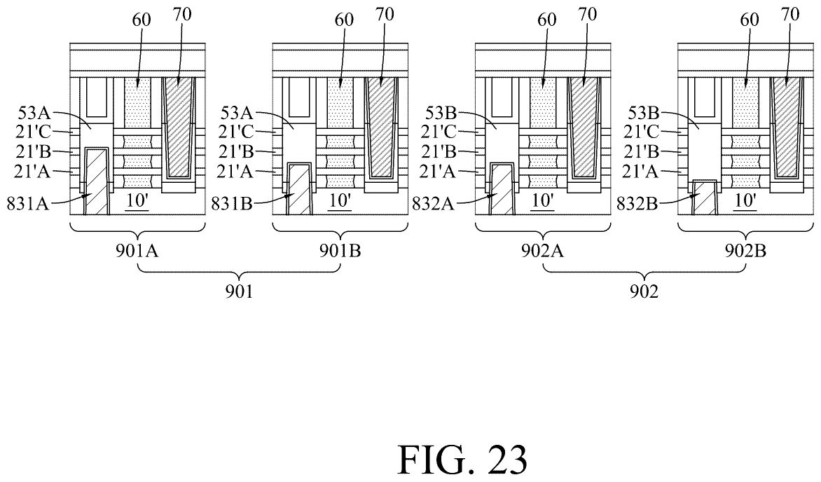

In some embodiments, as shown in FIGS. 23, 24, 25 and 26, the back side vias 831A, 831B, 832A, 832B are formed with three different depths (or more, in accordance to some other embodiments). In other embodiments, the smallest one of the back side vias 831A, 831B, 832A, 832B penetrates through the substrate 10′ and into the source/drain portion 53 of a corresponding one of the devices. In such cases, step 105 may include more patterning process than aforementioned. For instance, a first patterning process is performed to form shallow trenches that penetrate through the substrate 10′ and that terminates at the proximal surfaces of the source/drain portions 53 (so as to facilitate formation of the insulating layer 81); and then the processes of forming the mask (i.e., to cover trenches that no further patterning is required); patterning; and removing the mask are repeated, so as to sequentially form all the trenches that are capable of accommodating the back side vias 831A, 831B, 832A, 832B with increasing depths.

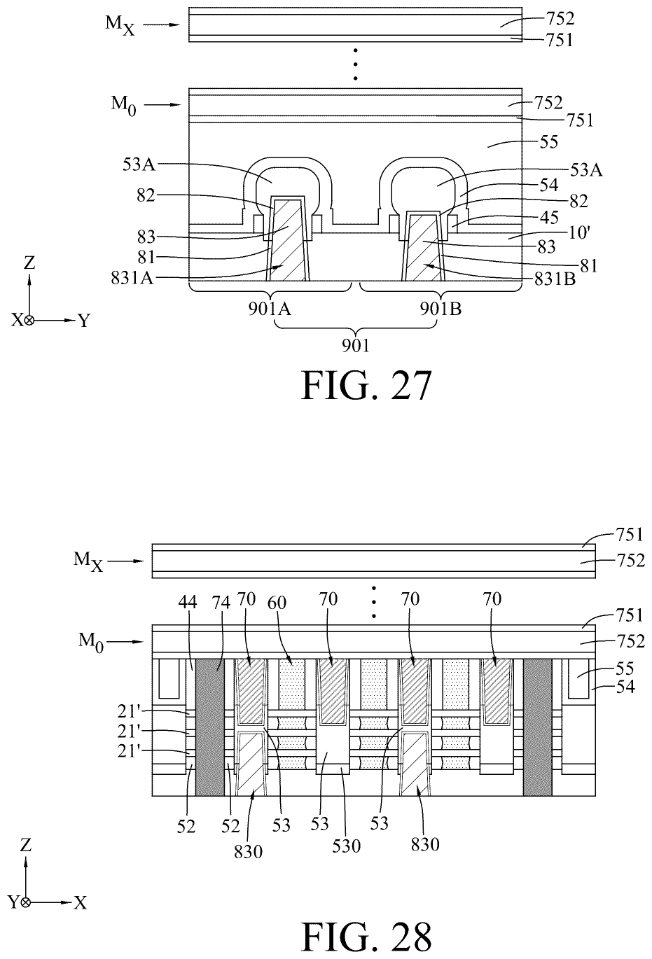

FIGS. 28 to 31 illustrate other possible configurations of the semiconductor structure in accordance with some embodiments. As shown in FIGS. 28 to 31, the back side vias, regardless of type of devices or conductivity types, are all denoted by the numeral 830.

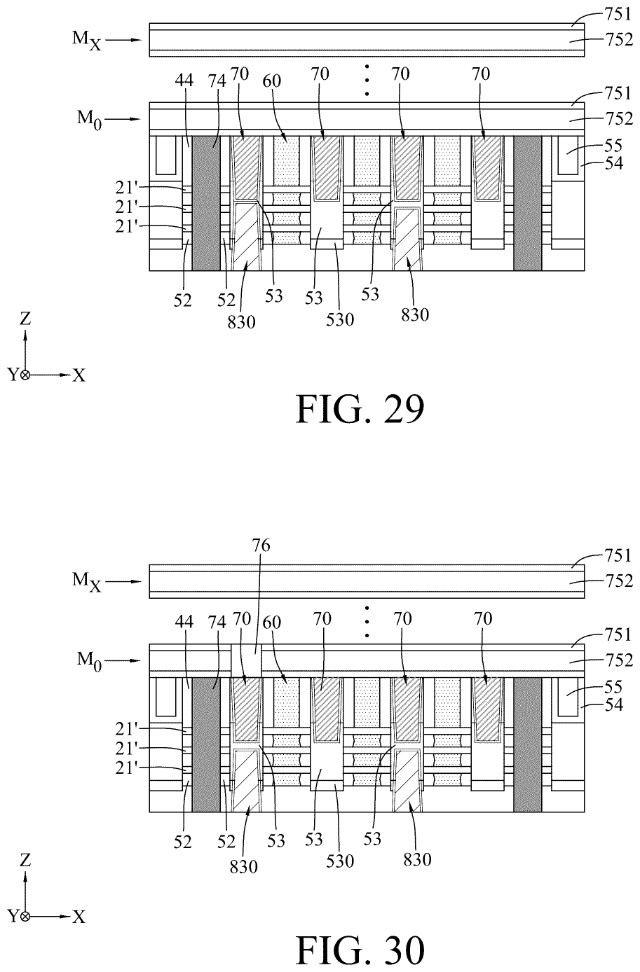

Referring back to FIGS. 19A and 20 to 26, in some embodiments, the source/drain contacts 70 (the front side contacts) and the back side vias (831, 832, 831A, 831B, 832A, 832B) penetrate into different source drain portions 53 of the devices, respectively. Referring to FIG. 28, in some embodiments, at least one of the source/drain contacts 70 and at least one of the back side vias 830 may penetrate into a same one of the source/drain portions 53. That is, within the one of the source/drain portions 53, the at least one of the source/drain contacts 70 is in position corresponding to the at least one of the back side vias 830 (which could be a memory via, or a logic via). Furthermore, referring to FIG. 29, in some embodiments, within the one of the source/drain portions 53, the at least one of the source/drain contacts 70 is in contact with the at least one of the back side vias 830 (which could be a memory via, or a logic via).

FIG. 30 illustrates that, in some embodiments, the devices may also be electrically connected to a front power routing (e.g., the Vdd or Vss for transmission of the supply voltage or the ground voltage) through a front side of the devices. Specifically, one of the source/drain portions 53 is connected to the front power routing through a corresponding one of the source/drain contacts 70 and the conductive portion 76 of the BEOL portion. In some embodiments, since routing at the back side of the devices is more relaxed than that of the front side, the back side vias 830 may have a size that is about 1.2 times to about 5 times larger than a size of the conductive portion 76.

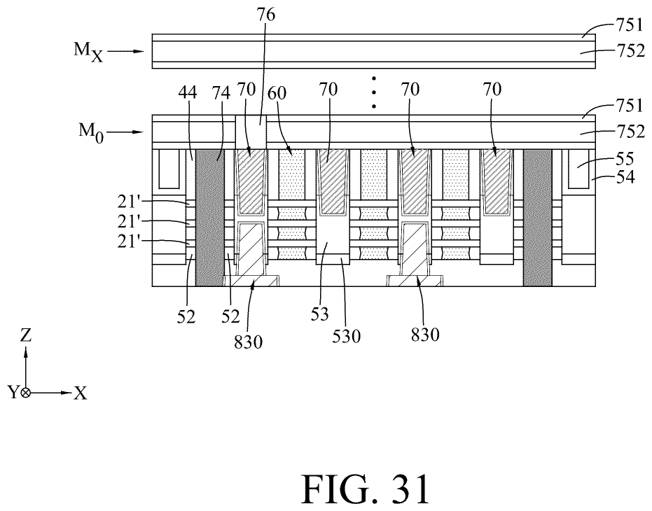

FIG. 31 illustrates that, in some embodiments, each of the back side vias 830 may be formed with a T-shape configuration, which allows the back side vias 830 to have a reduced contact resistance level.

The embodiments of the present disclosure have the following advantageous features. The logic vias 831 and the memory vias 832 are configured as the back side vias, and penetrate into source/drain portions 53 of the corresponding devices with different depths, allowing the logic devices to have a reduced contact resistance level, and the memory devices to have reduced current leakage, so as to enhance performance of both the logic devices and the memory devices.

In accordance with some embodiments of the present disclosure, a method for manufacturing semiconductor structure includes: forming first devices and second devices on a substrate, each of the first devices and the second devices including a source/drain portion and channel features that are connected to the source/drain portion; forming first device vias, each of which penetrates through the substrate and is connected to the source/drain portion of a respective one of the first devices; and forming second device vias, each of which penetrates through the substrate and is connected to the source/drain portion of a respective one of the second devices, a depth of the first device vias being different from a depth of the second device vias.

In accordance with some embodiments of the present disclosure, the depth of the first device vias is greater than the depth of the second device vias by not less than 2 nm.

In accordance with some embodiments of the present disclosure, the first devices include n-type first devices and p-type first devices; the first device vias include first vias that are respectively connected to the n-type first devices, and second vias that are respectively connected to the p-type first devices; the second devices include n-type second devices and p-type second devices; and the second device vias include first vias that are respectively connected to the n-type second devices, and second vias that are respectively connected to the p-type second devices.

In accordance with some embodiments of the present disclosure, a depth of the first vias of the first device vias is greater than a depth of the first vias of the second device vias.

In accordance with some embodiments of the present disclosure, a depth of the second vias of the first device vias is greater than a depth of the second vias of the second device vias.

In accordance with some embodiments of the present disclosure, a depth of the first vias of the first device vias is greater than a depth of the second vias of the first device vias.

In accordance with some embodiments of the present disclosure, a depth of the first vias of the second device vias is greater than a depth of the second vias of the second device vias.

In accordance with some embodiments of the present disclosure, forming the first device vias and the second device vias includes: performing a first patterning process to form first shallow trenches, each of which penetrates through the substrate and terminates at the source/drain portion of a respective one of the first devices, and to form second shallow trenches, each of which penetrates through the substrate and terminates at the source/drain portion of a respective one of the second devices; forming a mask to cover the second shallow trenches and to expose the first shallow trenches; performing a second patterning process to form the first shallow trenches into first deep trenches, each of which further penetrates into the source/drain portion of a respective one of the first devices; removing the mask; and forming the first device vias and the second device vias in the first deep trenches and the second shallow trenches, respectively.

In accordance with some embodiments of the present disclosure, at least one of the first device vias and the second device vias has a first section that is located within the source/drain portion of a corresponding one of the first devices and the second devices, and a second section that extends away from the first section into the substrate, the method further including forming an insulating layer around the second section of the at least one of the first device vias and the second device vias.

In accordance with some embodiments of the present disclosure, the method further includes forming a silicide layer around the first section of the at least one of the first device vias and the second device vias.

In accordance with some embodiments of the present disclosure, a method for manufacturing a semiconductor structure includes: forming first devices and second devices on a substrate, each of the first devices and the second devices including a source/drain portion and channel features that are connected to the source/drain portion; forming first device vias, each of the first device vias penetrating through the substrate and being connected to the source/drain portion of a respective one of the first devices; and forming second device vias, each of the second device vias penetrating through the substrate and being connected to the source/drain portion of a respective one of the second devices, each of the first device vias and the second device vias having a distal surface relative to the substrate, a first distance between the substrate and the distal surface of each of the first device vias being larger than a second distance between the substrate and the distal surface of each of the second device vias.

In accordance with some embodiments of the present disclosure, the first distance is larger than a third distance, the third distance being a distance between the substrate and a bottommost one of the channel features of the respective one of the first devices.

In accordance with some embodiments of the present disclosure, the second distance is less than a third distance, the third distance being a distance between the substrate and a bottommost one of the channel features of the respective one of the second devices.

In accordance with some embodiments of the present disclosure, a method further includes forming source/drain contacts, each of which penetrates into the source/drain portion of a respective one of the first devices and the second devices, and each of which is in position corresponding to a respective one of the first device vias and the second device vias.

In accordance with some embodiments of the present disclosure, at least one of the source/drain contacts is in contact with the corresponding one of the first device vias and the second device vias.

In accordance with some embodiments of the present disclosure, the first devices include n-type first devices and p-type first devices; the first device vias include first vias that are respectively connected to the n-type first devices, and second vias that are respectively connected to the p-type first devices; and a volume of the first vias of the first device vias is greater than a volume of the second vias of the first device vias.

In accordance with some embodiments of the present disclosure, the second devices include n-type second devices and p-type second devices; the second device vias includes first vias that are respectively connected to the n-type second devices, and second vias that are respectively connected to the p-type second devices; and a volume of the first vias of the second device vias is greater than a volume of the second vias of the second device vias.

In accordance with some embodiments of the present disclosure, a volume of the first device vias is greater than a volume of the second device vias.

In accordance with some embodiments of the present disclosure, a semiconductor structure includes: first devices, second devices, first device vias and second device vias. Each of the first devices and the second devices includes a source/drain portion and channel features that are connected to the source/drain portion. Each of the first device vias extends from a back side of a respective one of the first devices and is connected to the source/drain portion of the respective one of the first devices. Each of the second device vias extends from a back side of a respective one of the second devices and is connected to the source/drain portion of the respective one of the second devices. A volume of the first device vias is greater than a volume of the second device vias.

In accordance with some embodiments of the present disclosure, a depth of the first device vias is different from a depth of the second device vias.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming first devices and second devices on a substrate, each of the first devices and the second devices including a source/drain portion and channel features that are connected to the source/drain portion;
forming first device vias, each of which penetrates through the substrate and is connected to the source/drain portion of a respective one of the first devices; and
forming second device vias, each of which penetrates through the substrate and is connected to the source/drain portion of a respective one of the second devices,
a depth of the first device vias being different from a depth of the second device vias.

2. The method according to claim 1, wherein the depth of the first device vias is greater than the depth of the second device vias by not less than 2 nm.

3. The method according to claim 1, wherein:
the first devices include n-type first devices and p-type first devices;
the first device vias include first vias that are respectively connected to the n-type first devices, and second vias that are respectively connected to the p-type first devices;
the second devices include n-type second devices and p-type second devices; and
the second device vias include first vias that are respectively connected to the n-type second devices, and second vias that are respectively connected to the p-type second devices.

4. The method according to claim 3, wherein a depth of the first vias of the first device vias is greater than a depth of the first vias of the second device vias.

5. The method according to claim 3, wherein a depth of the second vias of the first device vias is greater than a depth of the second vias of the second device vias.

6. The method according to claim 3, wherein a depth of the first vias of the first device vias is greater than a depth of the second vias of the first device vias.

7. The method according to claim 3, wherein a depth of the first vias of the second device vias is greater than a depth of the second vias of the second device vias.

8. The method according to claim 1, wherein forming the first device vias and the second device vias includes:
performing a first patterning process to form first shallow trenches, each of which penetrates through the substrate and terminates at the source/drain portion of a respective one of the first devices, and to form second shallow trenches, each of which penetrates through the substrate and terminates at the source/drain portion of a respective one of the second devices;
forming a mask to cover the second shallow trenches and to expose the first shallow trenches;
performing a second patterning process to form the first shallow trenches into first deep trenches, each of which further penetrates into the source/drain portion of a respective one of the first devices;
removing the mask; and
forming the first device vias and the second device vias in the first deep trenches and the second shallow trenches, respectively.

9. The method according to claim 1, wherein at least one of the first device vias and the second device vias has a first section that is located within the source/drain portion of a corresponding one of the first devices and the second devices, and a second section that extends away from the first section into the substrate, the method further comprising forming an insulating layer around the second section of the at least one of the first device vias and the second device vias.

10. The method according to claim 9, further comprising forming a silicide layer around the first section of the at least one of the first device vias and the second device vias.

11. A method for manufacturing a semiconductor structure, comprising:
forming first devices and second devices on a substrate, each of the first devices and the second devices including a source/drain portion and channel features that are connected to the source/drain portion;
forming first device vias, each of the first device vias penetrating through the substrate and being connected to the source/drain portion of a respective one of the first devices; and
forming second device vias, each of the second device vias penetrating through the substrate and being connected to the source/drain portion of a respective one of the second devices,
each of the first device vias and the second device vias having a distal surface relative to the substrate, a first distance between the substrate and the distal surface of each of the first device vias being larger than a second distance between the substrate and the distal surface of each of the second device vias.

12. The method according to claim 11, wherein the first distance is larger than a third distance, the third distance being a distance between the substrate and a bottommost one of the channel features of the respective one of the first devices.

13. The method according to claim 11, wherein the second distance is less than a third distance, the third distance being a distance between the substrate and a bottommost one of the channel features of the respective one of the second devices.

14. The method according to claim 11, further comprising forming source/drain contacts, each of which penetrates into the source/drain portion of a respective one of the first devices and the second devices, and each of which is in position corresponding to a respective one of the first device vias and the second device vias.

15. The method according to claim 14, wherein at least one of the source/drain contacts is in contact with the corresponding one of the first device vias and the second device vias.

16. The method according to claim 11, wherein:
the first devices include n-type first devices and p-type first devices;
the first device vias include first vias that are respectively connected to the n-type first devices, and second vias that are respectively connected to the p-type first devices; and
a volume of the first vias of the first device vias is greater than a volume of the second vias of the first device vias.

17. The method according to claim 11, wherein:
the second devices include n-type second devices and p-type second devices;
the second device vias includes first vias that are respectively connected to the n-type second devices, and second vias that are respectively connected to the p-type second devices; and
a volume of the first vias of the second device vias is greater than a volume of the second vias of the second device vias.

18. The method according to claim 11, wherein a volume of the first device vias is greater than a volume of the second device vias.

19. A semiconductor structure, comprising:
first devices and second devices, each of the first devices and the second devices including a source/drain portion and channel features that are connected to the source/drain portion;
first device vias, each of which extends from a back side of a respective one of the first devices and is connected to the source/drain portion of the respective one of the first devices; and
second device vias, each of which extends from a back side of a respective one of the second devices and is connected to the source/drain portion of the respective one of the second devices,
a volume of the first device vias being greater than a volume of the second device vias.

20. The semiconductor structure according to claim 19, wherein a depth of the first device vias is different from a depth of the second device vias.
